(19) United States
(12) Patent Application Publication
(10) Pub. No.: US 2026/0068758 A1
(43) Pub. Date: Mar. 5, 2026

(54) HIGH BANDWIDTH MEMORY AND METHOD FOR MANUFACTURING THE SAME

(71) Applicant: Samsung Electronics Co., Ltd., Suwon-si (KR)

(72) Inventor: Jaesic LEE, Suwon-si (KR)

(73) Assignee: Samsung Electronics Co., Ltd., Suwon-si (KR)

(21) Appl. No.: 19/093,529

(22) Filed: Mar. 28, 2025

(30) Foreign Application Priority Data
Sep. 2, 2024 (KR) 10-2024-0118559

(51) Int. Cl. H01L 25/065; H01L 23/00; H01L 23/08; H01L 23/367; H10B 80/00

(52) U.S. Cl. CPC H01L 25/0657; H10B 80/00

(57) ABSTRACT

A high bandwidth memory including a first semiconductor stack including a plurality of first semiconductor dies stacked in a vertical direction; a glass core on the first semiconductor stack; and a second semiconductor stack on the glass core, the second semiconductor stack including a plurality of second semiconductor dies stacked in the vertical direction.

### CROSS-REFERENCE TO RELATED APPLICATION

This application claims priority to and the benefit of Korean Patent Application No. 10-2024-0118559 filed at the Korean Intellectual Property Office on Sep. 2, 2024, the entire contents of which are incorporated herein by reference.

### BACKGROUND

### (a) Field

The present disclosure relates to a high bandwidth memory and a method for manufacturing the same.

### (b) Description of Related Arts

A semiconductor industry sector is pursuing miniaturization, weight lightening, and thinning of a semiconductor package mounted on an electronic device while simultaneously achieving higher speed, multi-function, and large capacity in response to a demand for miniaturization and weight lightening of the electronic device. Accordingly, a need for a packaging technology capable of storing more data and transmitting data at a faster speed is increasing, and a high bandwidth memory (HBM) formed by stacking a plurality of individual semiconductor chips using the packaging technology is being developed and used (and may be beneficial).

The high bandwidth memory (HBM) may be manufactured by forming a memory stack in which memory dies are stacked on a base die, and as the number of memory dies disposed on the base die increases, it may be possible to implement the high bandwidth memory (HBM) having high performance. However, if the number of memory dies within the memory stack is increased so that the memory stack has a height above a certain height, a problem in which a stack void may occur at an interface between the memory dies at an upper portion of the memory stack and warpage may occur in the memory stack or heat may accumulate inside the memory stack so that performance of the high bandwidth memory (HBM) may be deteriorated, may occur.

### SUMMARY

A glass core to which a hybrid bonding process may be applied may be interposed between memory stacks. The memory stack may have a structure in which memory dies are stacked.

The glass core to which the hybrid bonding process may be applied may be interposed between memory stack structures. The memory stack structure may have a unit structure in which the stacked memory dies are covered by a molding material.

A base die and the memory dies may include dummy through-silicon vias. The dummy through-silicon vias may be electrically separated, and may be thermally connected to a heat dissipation structure.

Some example embodiments of inventive concepts include a first semiconductor stack including a plurality of first semiconductor dies stacked in a vertical direction; a glass core on the first semiconductor stack; and a second semiconductor stack on the glass core, the second semiconductor stack including a plurality of second semiconductor dies stacked in the vertical direction.

Some example embodiments of inventive concepts include a base die; a first memory stack structure on the base die, wherein the first memory stack structure includes a first lower bonding structure, a plurality of first memory dies stacked in a vertical direction on the first lower bonding structure, a first molding material covering the plurality of first memory dies on the first lower bonding structure, and a first upper bonding structure on the first molding material and the plurality of first memory dies; a glass interposer on the first memory stack structure, wherein the glass interposer includes a core base and a plurality of through-glass vias within the core base; and a second memory stack structure on the glass interposer, wherein the second memory stack structure includes a second lower bonding structure, a plurality of second memory dies stacked in the vertical direction on the second lower bonding structure, and a second molding material covering the plurality of second memory dies on the second lower bonding structure.

Some example embodiments of inventive concepts include a base die; a plurality of memory stacks stacked in a vertical direction on the base die, wherein each memory stack of the plurality of memory stacks includes a plurality of memory dies stacked in the vertical direction; one or more glass cores alternating with the plurality of memory stacks on the base die; and a molding material covering the plurality of memory stacks and the one or more glass cores on the base die.

Memory stacks or memory stack structures may be bonded by a glass core. As a result, it may be possible to prevent (or reduce a likelihood of) generation of a stack void at an interface between memory dies disposed at a high level, and it may be possible to reduce warpage of the memory dies disposed at the high level.

A high bandwidth memory may be manufactured in a separate process, and may be manufactured using the memory stack structures and the glass core that have been verified for reliability. Accordingly, a manufacturing process of the high bandwidth memory may be simplified, and productivity of the high bandwidth memory may be improved.

A base die and the memory dies may include dummy through-silicon vias. As a result, heat generated inside each of the base die and the memory dies may be released to the outside through the dummy through-silicon vias so that a heat dissipation characteristic of the high bandwidth memory is improved.

### BRIEF DESCRIPTION OF THE DRAWINGS

FIG. 1 is a cross-sectional view showing a high bandwidth memory of some example embodiments.

FIG. 2 is a cross-sectional view showing a glass core of some example embodiments.

FIG. 3 is a cross-sectional view showing the glass core of some example embodiments.

FIG. 4 is a cross-sectional view showing a high bandwidth memory of some example embodiments.

FIG. 5 is a cross-sectional view showing a high bandwidth memory of some example embodiments.

FIG. 6 is a cross-sectional view showing a high bandwidth memory of some example embodiments.

FIG. 7 is a cross-sectional view showing a high bandwidth memory including eight layers of memory dies.

FIG. 8 is a cross-sectional view showing a high bandwidth memory including 12 layers of memory dies.

FIG. 9 is a cross-sectional view showing a high bandwidth memory including 16 layers of memory dies.

FIG. 10 is a cross-sectional view of a high bandwidth memory including 24 layers of memory dies.

FIGS. 11 to 19 are cross-sectional views for describing a method for manufacturing the memory stack structures of FIG. 4 and FIG. 5.

FIGS. 20 to 23 are cross-sectional views showing a method for manufacturing the high bandwidth memory of FIG. 5.

FIGS. 24 to 31 are cross-sectional views showing a method for manufacturing the high bandwidth memory of FIG. 6.

### DETAILED DESCRIPTION

Various example embodiments of the present disclosure will be described more fully hereinafter with reference to the accompanying drawings so that those skilled in the art could implement the example embodiments. The present disclosure may be modified in various ways, all without departing from the spirit or scope of the present inventive concepts.

In order to describe the present inventive concepts, parts or portions that are irrelevant to the description are omitted, and identical or similar constituent elements throughout the specification are denoted by the same reference numerals.

In the drawings, a size and a thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. Unless explicitly stated to the contrary, the word “includes,” “comprise” and variations such as “comprises,” “including,” and “comprising” should be understood to imply the inclusion of stated elements but not the exclusion of any other elements.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

When the terms “approximately,” “about” or “substantially” are used in this specification in connection with a numerical value, it is intended that the associated numerical value includes a manufacturing or operational tolerance (e.g., ±10%) around the stated numerical value. Moreover, when the words “approximately,” “about” and “substantially” are used in connection with geometric shapes, it is intended that precision of the geometric shape is not required but that latitude for the shape is within the scope of the disclosure. Further, regardless of whether numerical values or shapes are modified as “approximately,” “about” or “substantially,” it will be understood that these values and shapes should be construed as including a manufacturing or operational tolerance (e.g., ±10%) around the stated numerical values or shapes.

It will be understood that elements and/or properties thereof may be recited herein as being “the same” or “equal” as other elements, and it will be further understood that elements and/or properties thereof recited herein as being “the same” as, or “equal” to other elements may be “the same” as, or “equal” to or “substantially the same” as or “substantially equal” to the other elements and/or properties thereof. Elements and/or properties thereof that are “substantially the same” as or “substantially equal” to other elements and/or properties thereof will be understood to include elements and/or properties thereof that are the same as, or equal to the other elements and/or properties thereof within manufacturing tolerances and/or material tolerances (e.g., ±10%). Elements and/or properties thereof that are the same or substantially the same as other elements and/or properties thereof may be structurally the same or substantially the same, functionally the same or substantially the same, and/or compositionally the same or substantially the same.

Hereinafter, high bandwidth memories (HBM) (100) 100A, 100B, 100C, and 100D of example embodiments and a method for manufacturing the same are described with reference to the drawings.

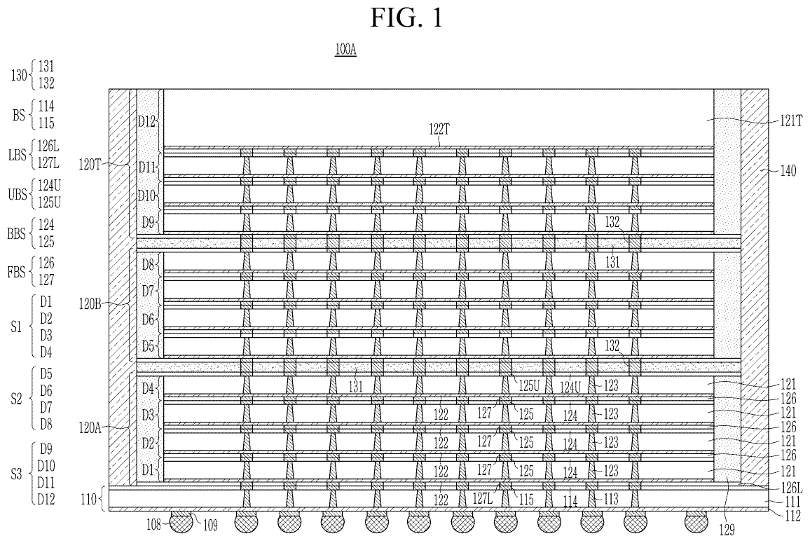

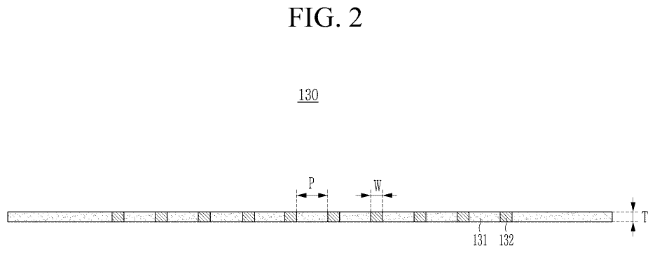

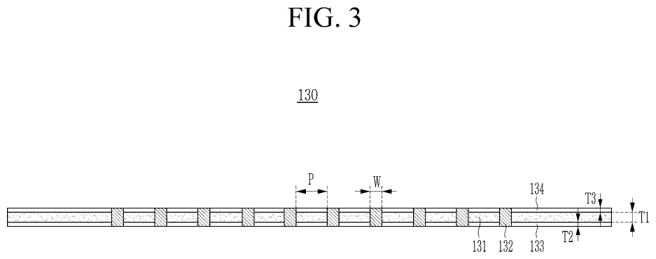

FIG. 1 is a cross-sectional view showing the high bandwidth memory 100A of some example embodiments. FIG. 2 and FIG. 3 are cross-sectional views showing a glass core 130 some example embodiments.

Referring to FIG. 1, the high bandwidth memory 100A may include external connection members 108, connection pads 109, a base die (or a base logic die) 110, memory stack structures (or semiconductor stack structures) (120) 120A, 120B, and 120T, and a molding material 140. The high bandwidth memory 100A may be a three-dimensional (3D) stacked dynamic random-access memory (DRAM) having high performance. The high bandwidth memory 100A may have memory channels through a memory stack manufactured by vertically stacking memory dies to simultaneously implement shorter latency and higher bandwidth compared with a conventional DRAM product, and may reduce a total area occupied by individual DRAMs on a substrate so that it may be advantageous for high bandwidth per area and may reduce power consumption.

Each of the external connection members 108 may be disposed between each of the connection pads 109 and an external device. Each of the external connection members 108 may electrically connect each of the connection pads 109 to the external device. In some example embodiments, the external connection members 108 may include a micro-bump or a solder ball. In some example embodiments, the external connection members 108 may include at least one of tin, silver, lead, nickel, copper, and an alloy thereof, but example embodiments are not limited thereto.

The connection pads 109 may be disposed below the base die 110. Each of the connection pads 109 may be disposed between each of wires within a frontside structure 112 of the base die 110 and each of the external connection members 108. Each of the connection pads 109 may electrically connect each of the wires within the frontside structure 112 of the base die 110 to each of the external connection members 108. In some example embodiments, the connection pads 109 may include at least one of copper, aluminum, tungsten, nickel, gold, tin, titanium, and an alloy thereof, but example embodiments are not limited thereto.

The base die 110 may be disposed between the memory dies (D) D1 to D12 and the external device. The base die 110 may be a buffer die. When data are exchanged between devices with different data processing speeds, processing units, and usage times, data loss may occur due to a difference in the data processing speeds, the processing units, and the usage times between the devices. To prevent (or reduce the likelihood of) the loss (or data loss), the base die 110 may be disposed between the memory dies D and the external device so that information when data are exchanged between the memory dies D and the external device may be temporarily stored (or may be stored) in the base die 110. In some example embodiments, when data are transmitted to or received from the memory dies D, the base die 110 may sequentially pass the data after arranging an order of the data.

The base die 110 may include a die base 111, the frontside structure 112, through-silicon vias 113, and a bonding structure BS.

The die base 111 may be disposed so that a frontside thereof faces the external connection members 108. The die base 111 may be a die formed from a wafer. In some example embodiments, the die base 111 may include silicon or another semiconductor material. The frontside structure 112 may be disposed between the die base 111 and the connection pads 109. The frontside structure 112 may include an active layer and a wiring layer. The active layer may be disposed on a frontside of the die base 111. The active layer may include an integrated circuit structure having integrated circuit regions. In some example embodiments, the integrated circuit structure may include at least one of an active device and a passive device. In some example embodiments, the integrated circuit structure may include a gate structure, a source region, and a drain region. In some example embodiments, the integrated circuit structure may include at least one of a transistor, a diode, a capacitor, an inductor, and a resistor. The wiring layer may be disposed on the active layer. The wiring layer may include signal wiring lines, electric power wiring lines, contact plugs, and an inter-metal dielectric (IMD).

The through-silicon vias 113 may be disposed within the die base 111. Each of the through-silicon vias 113 may be disposed between the active layer or the wiring layer of the frontside structure 112 and each of bonding pads 115 of the bonding structure BS. Each of the through-silicon vias 113 may electrically connect the active layer or the wiring layer of the frontside structure 112 to each of the bonding pads 115 of the bonding structure BS. In some example embodiments, the through-silicon vias 113 may include at least one of tungsten, aluminum, copper, and an alloy thereof, but example embodiments are not limited thereto.

The bonding structure BS may be disposed on a backside of the die base 111. The bonding structure BS may include a silicon insulating layer 114 and the bonding pads 115.

The silicon insulating layer 114 may be directly bonded to a lower silicon insulating layer 126L of the memory stack structures 120. The silicon insulating layer 114 may surround and insulate the bonding pads 115. In some example embodiments, the silicon insulating layer 114 may include silicon oxide. In some example embodiments, the silicon insulating layer 114 may include SiO₂, but example embodiments are not limited thereto.

The bonding pads 115 may be disposed through the silicon insulating layer 114. Levels of bonding surfaces of the bonding pads 115 may be the same as a level of a bonding surface of the silicon insulating layer 114. Side surfaces of the bonding pads 115 may be surrounded by the silicon insulating layer 114. Each of the bonding pads 115 may be electrically connected to each of the through-silicon vias 113. The bonding pads 115 may be directly bonded to lower bonding pads 127L of the memory stack structures 120. An electrical connection may be made between the base die 110 and the memory stack structures 120 by direct bonding between the bonding pads 115 and the lower bonding pads 127L. In some example embodiments, the bonding pads 115 may include copper or a conductive material capable of applying hybrid bonding.

The memory stack structures 120 may be disposed on the base die 110. The memory stack structures 120 may be sequentially stacked above the base die 110. In FIG. 1, the high bandwidth memory 100 including three memory stack structures 120A, 120B, and 120T is disclosed, but the example embodiments are not limited thereto, and the high bandwidth memory 100 including more or fewer memory stack structures 120 may be included within the scope of the present inventive concepts. The first memory stack structure 120A may include a lower bonding structure LBS, a memory stack (or a semiconductor stack) S1, a molding material 129, and an upper bonding structure UBS. The second memory stack structure 120B may include a lower bonding structure LBS, a memory stack (or a semiconductor stack) S2, a molding material 129, and an upper bonding structure UBS. The third memory stack structure 120T may include a lower bonding structure LBS, a memory stack (or a semiconductor stack) S3, and a molding material 129.

The lower bonding structure LBS may be disposed at a lowermost portion of the memory stack structure 120. The lower bonding structure LBS may include the lower silicon insulating layer 126L and the lower bonding pads 127L.

The lower silicon insulating layer 126L may be directly bonded to the silicon insulating layer 114 of the base die 110 or a core base 131. The lower silicon insulating layer 126L may surround and insulate the lower bonding pads 127L. In some example embodiments, the lower silicon insulating layer 126L may include a material capable of performing non-metal-non-metal hybrid bonding with the silicon insulating layer 114 of the base die 110 or the core base 131. In some example embodiments, the lower silicon insulating layer 126L may include silicon oxide. In some example embodiments, the lower silicon insulating layer 126L may include SiO₂, but example embodiments are not limited thereto.

The lower bonding pads 127L may be disposed through the lower silicon insulating layer 126L. Levels of bonding surfaces of the lower bonding pads 127L may be the same as a level of a bonding surface of the lower silicon insulating layer 126L. Side surfaces of the lower bonding pads 127L may be surrounded by the lower silicon insulating layer 126L. Each of the lower bonding pads 127L may be electrically connected to each of wires within a frontside structure 122 of the memory die D adjacent to each of the lower bonding pads 127L. The lower bonding pads 127L may be directly bonded to the bonding pads 115 of the base die 110 or through-glass vias 132 of the glass core 130. An electrical connection may be made between the base die 110 and the memory stack structure 120 or between the glass core 130 and the memory stack structure 120 by direct bonding between the lower bonding pads 127L and the bonding pads 115 or the through-glass vias 132. In some example embodiments, the lower bonding pads 127L may include copper or a conductive material capable of applying hybrid bonding.

Memory stacks(S) S1, S2, and S3 may be disposed on the lower bonding structure LBS. The memory stack S may include the memory dies D stacked in a vertical direction. In FIG. 1, the memory stack S including four memory dies D is disclosed, but the example embodiments are not limited thereto, and the memory stack S including more or fewer memory dies D may be included within the scope of the present inventive concepts.

The memory die (a semiconductor die or a core die) D may include a memory die base 121, the frontside structure 122, a frontside bonding structure FBS, through-silicon vias 123, and a backside bonding structure BBS. The memory dies D1, D5, and D9 adjacent to the lower bonding structure LBS may not include the frontside bonding structure FBS. The memory dies D4 and D8 adjacent to the upper bonding structure UBS may not include the backside bonding structure BBS. The memory die D12 disposed at an uppermost portion of the high bandwidth memory 100A may not include the through-silicon vias 123 and the backside bonding structure BBS. In some example embodiments, the memory dies D may each include a DRAM, but example embodiments are not limited thereto.

The memory die base 121 may be disposed so that a frontside thereof faces the external connection members 108. The memory die base 121 may be a die formed from a wafer. In some example embodiments, the memory die base 121 may include silicon or another semiconductor material.

The frontside structure 122 may be disposed on a frontside of the memory die base 121. The frontside structure 122 may include an active layer and a wiring layer. The active layer may be disposed on the frontside of the memory die base 121. The active layer may include an integrated circuit structure having integrated circuit regions. In some example embodiments, the integrated circuit structure may include at least one of an active device and a passive device. In some example embodiments, the integrated circuit structure may include a gate structure, a source region, and a drain region. In some example embodiments, the integrated circuit structure may include at least one of a transistor, a diode, a capacitor, an inductor, and a resistor. The wiring layer may be disposed on the active layer. The wiring layer may include signal wiring lines, electric power wiring lines, contact plugs, and an inter-metal dielectric (IMD).

The frontside bonding structure FBS may be disposed on the frontside structure 122. The frontside bonding structure FBS may include a frontside silicon insulating layer 126 and frontside bonding pads 127.

The frontside silicon insulating layer 126 may be directly bonded to a backside silicon insulating layer 124 of the memory die D adjacent to the frontside silicon insulating layer 126. The frontside silicon insulating layer 126 may surround and insulate the frontside bonding pads 127. In some example embodiments, the frontside silicon insulating layer 126 may include silicon oxide. In some example embodiments, the frontside silicon insulating layer 126 may include SiO₂, but example embodiments are not limited thereto.

The frontside bonding pads 127 may be disposed through the frontside silicon insulating layer 126. Levels of bonding surfaces of the frontside bonding pads 127 may be the same as a level of a bonding surface of the frontside silicon insulating layer 126. Side surfaces of the frontside bonding pads 127 may be surrounded by the frontside silicon insulating layer 126. Each of the frontside bonding pads 127 may be electrically connected to each of the wires within the frontside structure 122. The frontside bonding pads 127 may be directly bonded to backside bonding pads 125 of the memory die D adjacent to the frontside bonding pads 127. An electrical connection may be made between the memory dies D by direct bonding between the frontside bonding pads 127 and the backside bonding pads 125. In some example embodiments, the frontside bonding pads 127 may include copper or a conductive material capable of applying hybrid bonding.

The through-silicon vias 123 may be disposed within the memory die base 121. Each of the through-silicon vias 123 may be disposed between the active layer or the wiring layer of the frontside structure 122 and each of the backside bonding pads 125 of the backside bonding structure BBS. Each of the through-silicon vias 123 may electrically connect the active layer or the wiring layer of the frontside structure 122 to each of the backside bonding pads 125 of the backside bonding structure BBS. In some example embodiments, the through-silicon vias 123 may include at least one of tungsten, aluminum, copper, and an alloy thereof, but example embodiments are not limited thereto.

The backside bonding structure BBS may be disposed on a backside of the memory die base 121. The backside bonding structure BBS may include the backside silicon insulating layer 124 and the backside bonding pads 125.

The backside silicon insulating layer 124 may be directly bonded to the frontside silicon insulating layer 126 of the memory die D adjacent to the backside silicon insulating layer 124. The backside silicon insulating layer 124 may surround and insulate the backside bonding pads 125. In some example embodiments, the backside silicon insulating layer 124 may include silicon oxide. In some example embodiments, the backside silicon insulating layer 124 may include SiO₂, but example embodiments are not limited thereto.

The backside bonding pads 125 may be disposed through the backside silicon insulating layer 124. Levels of bonding surfaces of the backside bonding pads 125 may be the same as a level of a bonding surface of the backside silicon insulating layer 124. Side surfaces of the backside bonding pads 125 may be surrounded by the backside silicon insulating layer 124. Each of the backside bonding pads 125 may be electrically connected to each of the through-silicon vias 123. The backside bonding pads 125 may be directly bonded to the frontside bonding pads 127 of the memory die D adjacent to the backside bonding pads 125. An electrical connection may be made between the memory dies D by direct bonding between the backside bonding pads 125 and the frontside bonding pads 127. In some example embodiments, the backside bonding pads 125 may include copper or a conductive material capable of applying hybrid bonding.

The molding material 129 may be disposed on the lower bonding structure LBS, and may cover the memory stack S. The molding material 129 may have the same level as a level of an upper surface of the memory stack S.

The upper bonding structure UBS may be disposed on the memory stack S and the molding material 129. The upper bonding structure UBS may include an upper silicon insulating layer 124U and upper bonding pads 125U.

The upper silicon insulating layer 124U may be directly bonded to the core base 131. The upper silicon insulating layer 124U may surround and insulate the upper bonding pads 125U. In some example embodiments, the upper silicon insulating layer 124U may include a material capable of performing non-metal-non-metal hybrid bonding with the core base 131. In some example embodiments, the upper silicon insulating layer 124U may include silicon oxide. In some example embodiments, the upper silicon insulating layer 124U may include SiO₂, but example embodiments are not limited thereto.

The upper bonding pads 125U may be disposed through the upper silicon insulating layer 124U. Levels of bonding surfaces of the upper bonding pads 125U may be the same as a level of a bonding surface of the upper silicon insulating layer 124U. Side surfaces of the upper bonding pads 125U may be surrounded by the upper silicon insulating layer 124U. Each of the upper bonding pads 125U may be electrically connected to each of the through-silicon vias 123 of the memory die D adjacent to each of the upper bonding pads 125U. The upper bonding pads 125U may be directly bonded to the through-glass vias 132 of the glass core 130. An electrical connection may be made between the glass core 130 and the memory stack structure 120 by direct bonding between the upper bonding pads 125U and the through-glass vias 132. In some example embodiments, the upper bonding pads 125U may include copper or a conductive material capable of applying hybrid bonding.

Referring to FIG. 1 and FIG. 2, glass cores (or glass interposers) 130 may be stacked alternately with the memory stack structures 120 on the base die 110. Each of the glass cores 130 may be disposed between the memory stack structures 120 adjacent to each other. The glass core 130 may include the core base 131 and the through-glass vias (or first through-glass vias) 132.

A first surface of the core base 131 may be directly bonded to the upper silicon insulating layer 124U of the upper bonding structure UBS of the memory stack structure 120. A second surface of the core base 131 may be directly bonded to the lower silicon insulating layer 126L of the lower bonding structure LBS of the memory stack structure 120. The second surface may be an opposite surface of the first surface. The core base 131 may surround and insulate the through-glass vias 132. In some example embodiments, the core base 131 may include quartz. In some example embodiments, the core base 131 may include silicon oxide. In some example embodiments, the core base 131 may include SiO₂, but example embodiments are not limited thereto. In some example embodiments, the core base 131 may have a thickness T in a vertical direction ranging from about 1 μm to about 100 μm, but example embodiments are not limited thereto.

The through-glass vias 132 may be disposed through the core base 131. Each first end (or each first bonding surface) of the through-glass vias 132 may be directly bonded to a corresponding the upper bonding pad 125U among the upper bonding pads 125U of the upper bonding structure UBS of the memory stack structure 120. Each second end (or each second bonding surface) of the through-glass vias 132 may be directly bonded to a corresponding the lower bonding pad 127L among the lower bonding pads 127L of the lower bonding structure LBS of the memory stack structure 120. The second end may be a portion opposite to the first end. An electrical connection may be made between the memory stack structures 120 by the direct bonding. A level of each first end (or each first bonding surface) of the through-glass vias 132 may be the same as a level of the first surface of the core base 131. A level of each second end (or each second bonding surface) of the through-glass vias 132 may be the same as a level of the second surface of the core base 131. Side surfaces of the through-glass vias 132 may be surrounded by the core base 131. In some example embodiments, the through-glass vias 132 may include copper or a conductive material capable of applying hybrid bonding. In some example embodiments, each of the through-glass vias 132 may have a width W in a horizontal direction ranging from about 0.01 μm to about 30 μm, but example embodiments are not limited thereto. In some example embodiments, adjacent through-glass vias 132 may be disposed with an interval P in a horizontal direction ranging from about 1 μm to about 30 μm, but example embodiments are not limited thereto.

Like a silicon material, a glass material may be formed so that a surface roughness thereof is about 10 nm or less, but example embodiments are not limited thereto. Accordingly, it may be possible to form the through-glass vias 132 having an ultra-fine pitch within the core base 131 of the glass material, and an interconnection structure capable of performing hybrid bonding may be formed based on the through-glass vias 132 including copper and the core base 131 including silicon oxide.

A Young's modulus of the glass material may be about 50 to about 90 GPa, but example embodiments are not limited thereto. A Young's modulus of the silicon material may be about 165 GPa, but example embodiments are not limited thereto. Additionally or alternatively, a coefficient of thermal expansion (CTE) of the glass material may be about 3 to about 9 ppm/K, but example embodiments are not limited thereto. The coefficient of thermal expansion (CTE) of the silicon material may be about 2.9 to about 4 ppm/K, but example embodiments are not limited thereto. Because the glass material is more flexible than the silicon material and the core base 131 made of the glass material has a similar coefficient of thermal expansion to that of silicon that is a main material of the memory die D, a warpage characteristic that may occur due to a difference in coefficient of thermal expansion between the materials may be improved.

The glass material may have excellent flatness (or the glass material may have a flat surface and/shape). Therefore, if the core base 131 made of the glass material is used, a phenomenon of dishing and erosion occurring in a chemical mechanical polishing (CMP) process performed in a previous step of a hybrid bonding process may be adjusted. Thus, it may be possible to solve a problem of poor connection between bonding pads.

Referring to FIG. 3, the glass core 130 may include a first silicon insulating layer 133 on the first surface of the core base 131. The glass core 130 may include a second silicon insulating layer 134 on the second surface of the core base 131.

The first silicon insulating layer 133 may be directly bonded to the upper silicon insulating layer 124U of the upper bonding structure UBS of the memory stack structure 120. The second silicon insulating layer 134 may be directly bonded to the lower silicon insulating layer 126L of the lower bonding structure LBS of the memory stack structure 120. The core base 131, the first silicon insulating layer 133, and the second silicon insulating layer 134 may surround and insulate the through-glass vias 132. In some example embodiments, the first silicon insulating layer 133 and the second silicon insulating layer 134 may each include silicon nitride. In some example embodiments, each of the first silicon insulating layer 133 and the second silicon insulating layer 134 may include SiN or SiCN, but example embodiments are not limited thereto. In an example embodiment where the first silicon insulating layer 133 and the second silicon insulating layer 134 include SiN, the lower silicon insulating layer 126L, the upper silicon insulating layer 124U, the frontside silicon insulating layer 126, and the backside silicon insulating layer 124 may each include SiN other than SiO₂, but example embodiments are not limited thereto. In an example embodiment where the first silicon insulating layer 133 and the second silicon insulating layer 134 include SiCN, the lower silicon insulating layer 126L, the upper silicon insulating layer 124U, the frontside silicon insulating layer 126, and the backside silicon insulating layer 124 may each include SiCN other than SiO₂, but example embodiments are not limited thereto. In some example embodiments, the core base 131 may have a thickness T1 in a vertical direction ranging from about 1 μm to about 100 μm, but example embodiments are not limited thereto. In some example embodiments, the first silicon insulating layer 133 may have a thickness T2 in the vertical direction ranging from about 0.05 μm to about 1 μm, but example embodiments are not limited thereto. In some example embodiments, the second silicon insulating layer 134 may have a thickness T3 in the vertical direction ranging from about 0.05 μm to about 1 μm, but example embodiments are not limited thereto.

The through-glass vias 132 may be disposed through the core base 131, the first silicon insulating layer 133, and the second silicon insulating layer 134. The level of each first end (or each first bonding surface) of the through-glass vias 132 may be the same as a level of a bonding surface of the first silicon insulating layer 133. The level of each second end (or each second bonding surface) of the through-glass vias 132 may be the same as a level of a bonding surface of the second silicon insulating layer 134. The side surfaces of the through-glass vias 132 may be surrounded by the core base 131, the first silicon insulating layer 133, and the second silicon insulating layer 134.

The contents described with respect to the glass core 130 of FIG. 2 may be applied to the contents other than those described with respect to the glass core 130 of FIG. 3.

Referring back to FIG. 1, the molding material 140 may be disposed on the base die 110, and may cover the memory stack structures 120 and the glass cores 130. The molding material 140 may have the same level as a level of an upper surface of the third memory stack structure 120T.

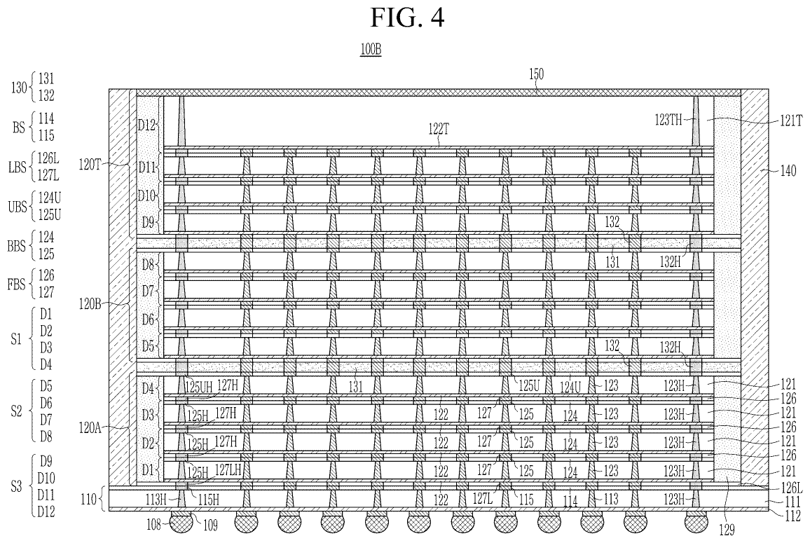

FIG. 4 is a cross-sectional view showing the high bandwidth memory 100B according to some example embodiments.

Referring to FIG. 4, a third memory stack structure 120T disposed at an uppermost portion of memory stack structures 120 may include a lower bonding structure LBS, a memory stack (or a semiconductor stack) S3, a molding material 129, and a heat dissipation structure 150.

The heat dissipation structure 150 may be disposed on the molding material 129 and the memory stack S3. In some example embodiments, the heat dissipation structure 150 may include a heat slug, a heat sink, or a heat spreader, but example embodiments are not limited thereto. In some example embodiments, the heat dissipation structure 150 may include a conductive material having high thermal conductivity such as silicon, copper or aluminum, but example embodiments are not limited thereto. In some example embodiments, the heat dissipation structure 150 may include a thermal interface material (TIM). In some example embodiments, the thermal interface material (TIM) may include a thermal paste, a thermal pad, a phase change material (PCM), or a metal material, but example embodiments are not limited thereto. In some example embodiments, the thermal interface material (TIM) may include grease.

A base die 110, the memory stack structures 120, and glass cores 130 may include dummy structures H thermally connected to the heat dissipation structure 150 (components in which H is added after a reference numeral of the drawings). The base die 110 may include dummy through-silicon vias 113H within a die base 111 and dummy bonding pads 115H of a bonding structure BS. The lower bonding structure LBS of each of the memory stack structures 120 may include lower dummy bonding pads 127LH. The upper bonding structure UBS of each of the memory stack structures 120 may include upper dummy bonding pads 125UH. Each of memory dies D may include dummy through-silicon vias 123H, dummy frontside bonding pads 127H of a frontside bonding structure FBS, and dummy backside bonding pads 125H of a backside bonding structure BBS. Each of the glass cores 130 may include dummy through-glass vias (or second through-glass vias) 132H.

The dummy structures H may be electrically separated, and may be thermally connected to the heat dissipation structure 150. The dummy structures H may be disposed at edges of the base die 110, the memory dies D, and the glass cores 130 on a plane. The dummy structures H corresponding to each other may be connected in a line in a vertical direction. Heat generated from the base die 110 and the memory dies D may be transferred to the heat dissipation structure 150 through the dummy structures H, and may be released to the outside through the heat dissipation structure 150. Accordingly, a heat dissipation characteristic of the high bandwidth memory 100B may be improved.

The contents described with respect to the high bandwidth memory 100A of FIG. 1 may be applied to the contents other than those described with respect to the high bandwidth memory 100B of FIG. 4.

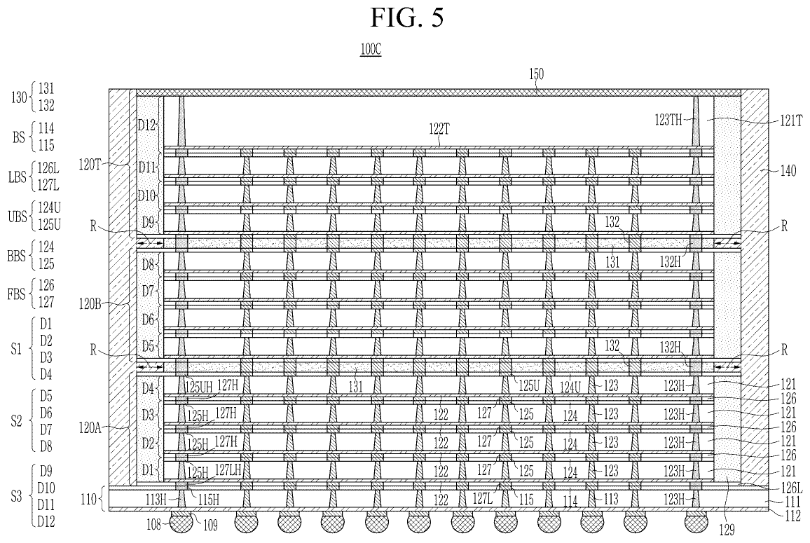

FIG. 5 is a cross-sectional view showing the high bandwidth memory 100C of some example embodiments.

Referring to FIG. 5, each of side surfaces of a core base 131 of a glass core 130 may be recessed (R) based on a corresponding side surface of the side surfaces of molding material 129 of memory stack structures 120, a corresponding side surface of side surfaces of a lower bonding structure LBS, and a corresponding side surface of side surfaces of an upper bonding structure UBS. A molding material 140 covering the memory stack structures 120 and glass cores 130 may extend to contact the recessed side surfaces of the core base 131.

According to the present inventive concepts, the recessed side surfaces of the core bases 131, a portion of a lower surface, and a portion of an upper surface of the memory stack structures 120 may be covered by the molding material 140. Accordingly, it may be possible to improve an adhesive force of the molding material 140 to the core bases 131 and the memory stack structures 120. Additionally or alternatively, a progress of delamination or a crack that may occur along an interface between the molding material 129 and the molding material 140 may be prevented (or reduced) by the molding material 140 extending to contact the side surfaces of the core base 131, so that damage to the memory stack structures 120 may be prevented (or reduced).

The contents described with respect to the high bandwidth memory 100B of FIG. 4 may be applied to the contents other than those described with respect to the high bandwidth memory 100C of FIG. 5.

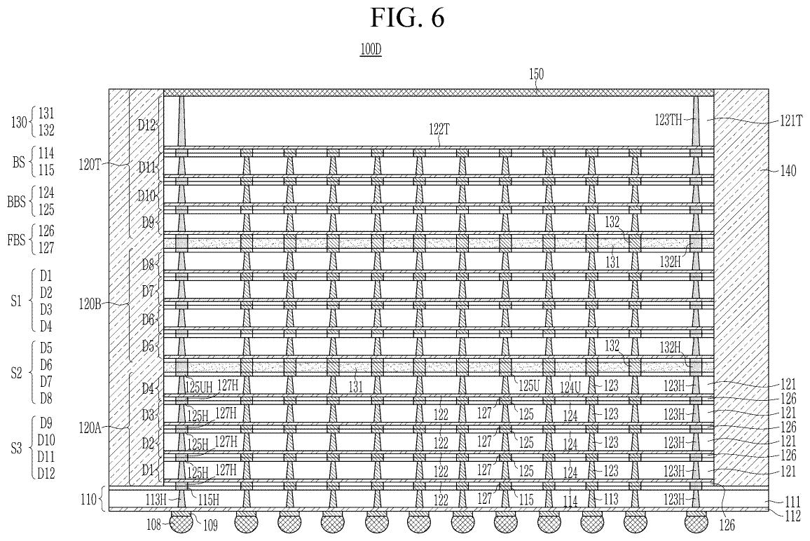

FIG. 6 is a cross-sectional view showing the high bandwidth memory 100D of some example embodiments.

Referring to FIG. 6, the high bandwidth memory 100D may include a base die 110, memory stacks(S) S1, S2, and S3, glass cores 130, and a molding material 140. The memory stacks S may be stacked in a vertical direction on the base die 110. The glass cores 130 may be stacked alternately with the memory stacks S on the base die 110. The memory stack S1 may include memory dies D1 to D4 stacked in the vertical direction. The memory stack S2 may include memory dies D5 to D8 stacked in the vertical direction. The memory stack S3 may include memory dies D9 to D12 stacked in the vertical direction. The molding material 140 may cover the memory stacks S and the glass cores 130 on the base die 110.

The memory die D may include a frontside bonding structure FBS and a backside bonding structure BBS.

The frontside bonding structure FBS may be disposed on a frontside structure 122. The frontside bonding structure FBS may include a frontside silicon insulating layer 126 and frontside bonding pads 127. The frontside silicon insulating layer 126 may be directly bonded to a silicon insulating layer 114 of the base die 110, a backside silicon insulating layer 124 of the memory die D adjacent to the frontside silicon insulating layer 126, or a core base 131 of the glass core 130 adjacent to the frontside silicon insulating layer 126. The frontside bonding pads 127 may be directly bonded to bonding pads 115 of the base die 110, backside bonding pads 125 of the memory die D adjacent to the frontside bonding pads 127, or through-glass vias 132 of the glass core 130.

The backside bonding structure BBS may be disposed on a backside of a memory die base 121. The backside bonding structure BBS may include the backside silicon insulating layer 124 and the backside bonding pads 125. The backside silicon insulating layer 124 may be directly bonded to the frontside silicon insulating layer 126 of the memory die D adjacent to the backside silicon insulating layer 124 or the core base 131 of the glass core 130 adjacent to the backside silicon insulating layer 124. The backside bonding pads 125 may be directly bonded to the frontside bonding pads 127 of the memory die D adjacent to the backside bonding pads 125 or the through-glass vias 132 of the glass core 130 adjacent to the backside bonding pads 125.

The glass core 130 may include the core base 131 and the through-glass vias 132. A first surface of the core base 131 may be directly bonded to the backside silicon insulating layer 124 of the memory die D adjacent to the first surface of the core base 131. A second surface of the core base 131 may be directly bonded to the frontside silicon insulating layer 126 of the memory die D adjacent to the second surface of the core base 131. The second surface may be an opposite surface of the first surface.

The through-glass vias 132 may be disposed through (or disposed penetrating) the core base 131. A first end (or a first bonding surface) of each of the through-glass vias 132 may be directly bonded to a corresponding the backside bonding pad 125 among the backside bonding pads 125 of the memory die D adjacent to each first end. A second end (or A second bonding surface) of each of the through-glass vias 132 may be directly bonded to a corresponding frontside bonding pad 127 among the frontside bonding pads 127 of the memory die D adjacent to each second end. The second section may be a portion opposite to the first end.

The contents described with respect to the high bandwidth memory 100B of FIG. 4 may be applied to the contents other than those described with respect to the high bandwidth memory 100D of FIG. 6.

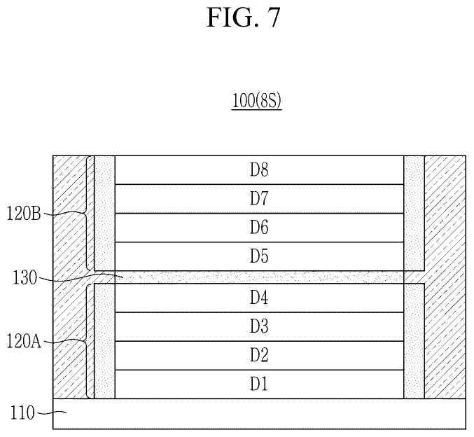

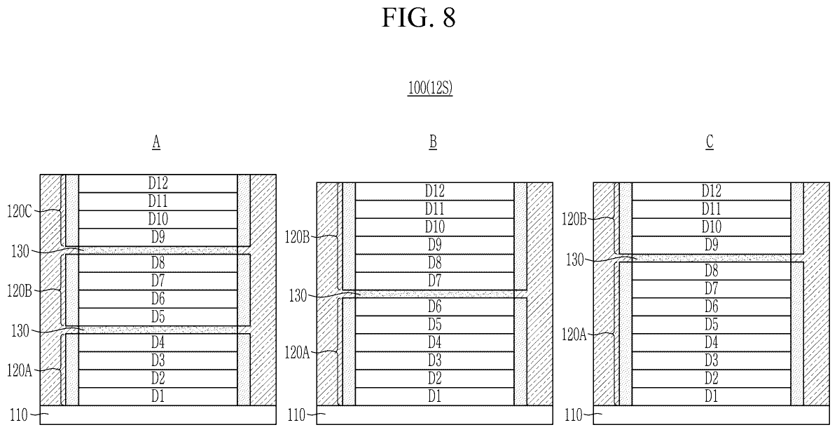

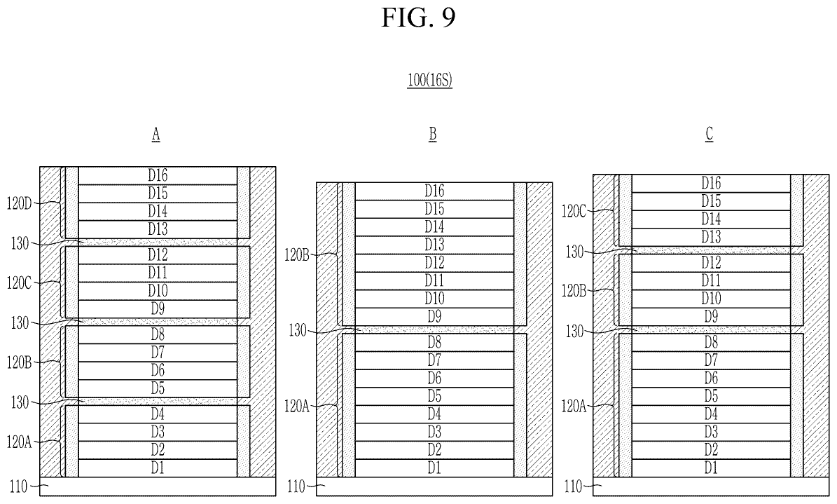

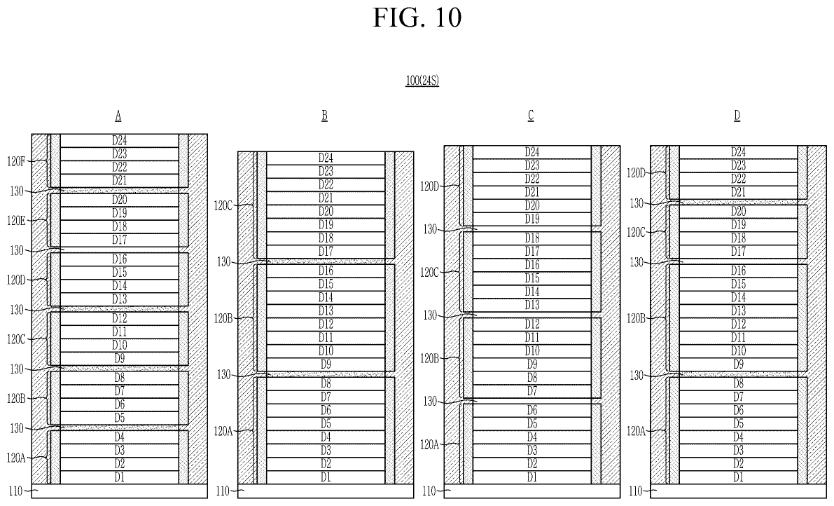

FIG. 7 is a cross-sectional view showing a high bandwidth memory 100 (8S) including eight layers of memory dies D. FIG. 8 is a cross-sectional view showing a high bandwidth memory 100 (12S) including 12 layers of memory dies D. FIG. 9 is a cross-sectional view showing a high bandwidth memory 100 (16S) including 16 layers of memory dies D. FIG. 10 is a cross-sectional view showing a high bandwidth memory 100 (24S) including 24 layers of memory dies D.

Referring to FIGS. 7 to 10, memory stack structures 120 may include the same number of memory dies D, or may include different numbers of memory dies D. If the stacked memory dies have a height greater than or equal to a predetermined (or desired) height, a stack void may occur at an interface between the memory dies disposed at a high level. The number of the memory dies D included in a memory stack structure 120 may be designed in consideration of a height at which the memory dies may be stacked without occurrence of the stack void and efficiency of a manufacturing process of the memory stack structure 120.

Referring to FIG. 7, the high bandwidth memory 100 (8S) of some example embodiments may include a first memory stack structure 120A including four memory dies D1 to D4 and a second memory stack structure 120B including four memory dies D5 to D8. Referring to FIG. 8, the high bandwidth memory 100 (12S) of an example embodiment A may include a first memory stack structure 120A including four memory dies D1 to D4, a second memory stack structure 120B including four memory dies D5 to D8, and a third memory stack structure 120C including four memory dies D9 to D12. The high bandwidth memory 100 (12S) of an example embodiment B may include a first memory stack structure 120A including six memory dies D1 to D6 and a second memory stack structure 120B including six memory dies D7 to D12. The high bandwidth memory 100 (12S) of an example embodiment C may include a first memory stack structure 120A including eight memory dies D1 to D8 and a second memory stack structure 120B including four memory dies D9 to D12.

Referring to FIG. 9, the high bandwidth memory 100 (16S) of an example embodiment A may include a first memory stack structure 120A including four memory dies D1 to D4, a second memory stack structure 120B including four memory dies D5 to D8, a third memory stack structure 120C including four memory dies D9 to D12, and a fourth memory stack structure 120D including four memory dies D13 to D16. The high bandwidth memory 100 (16S) of an example embodiment B may include a first memory stack structure 120A including eight memory dies D1 to D8 and a second memory stack structure 120B including eight memory dies D9 to D16. A high bandwidth memory 100 (16S) of an example embodiment C may include a first memory stack structure 120A including eight memory dies D1 to D8, a second memory stack structure 120B including four memory dies D9 to D12, and a third memory stack structure 120C including four memory dies D13 to D16.

Referring to FIG. 10, the high bandwidth memory 100 (24S) of an example embodiment A may include a first memory stack structure 120A including four memory dies D1 to D4, a second memory stack structure 120B including four memory dies D5 to D8, a third memory stack structure 120C including four memory dies D9 to D12, a fourth memory stack structure 120D including four memory dies D13 to D16, a fifth memory stack structure 120E including four memory dies D17 to D20, and a sixth memory stack structure 120F including four memory dies D21 to D24. The high bandwidth memory 100 (24S) of an example embodiment B may include a first memory stack structure 120A including eight memory dies D1 to D8, a second memory stack structure 120B including eight memory dies D9 to D16, and a third memory stack structure 120C including eight memory dies D17 to D24. The high bandwidth memory 100 (24S) of an example embodiment C may include a first memory stack structure 120A including six memory dies D1 to D6, a second memory stack structure 120B including six memory dies D7 to D12, a third memory stack structure 120C including six memory dies D13 to D18, and a fourth memory stack structure 120D including six memory dies D19 to D24. The high bandwidth memory 100 (24S) of an example embodiment (D) may include a first memory stack structure 120A including eight memory dies D1 to D8, a second memory stack structure 120B including eight memory dies D9 to D16, a third memory stack structure 120C including four memory dies D17 to D20, and a fourth memory stack structure 120D including four memory dies D21 to D24.

The number of the memory dies D included in each memory stack structure 120 is not limited to the above-described example embodiments, and the memory stack structure 120 including various numbers of memory dies D may be included within the scope of the present inventive concepts.

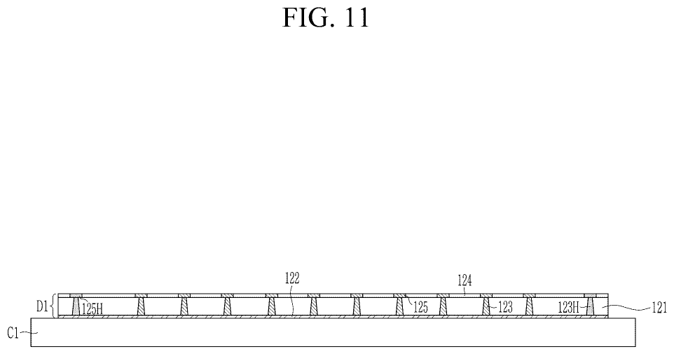

FIGS. 11 to 19 are cross-sectional views for describing a method for manufacturing the memory stack structures 120 of FIG. 4 and FIG. 5. The method for manufacturing the memory stack structures 120 of FIGS. 11 to 19 may be applied to a method for manufacturing the memory stack structure 120 of FIG. 1.

FIG. 11 is the cross-sectional view showing a step of attaching the first memory die D1 on a first carrier C1.

Referring to FIG. 11, the first memory die D1 may be attached on the first carrier C1. In some example embodiments, the first carrier C1 may include a silicon-based material such as glass or silicon oxide, another material such as an organic material or aluminum oxide, any combination thereof, or the like, but example embodiments are not limited thereto.

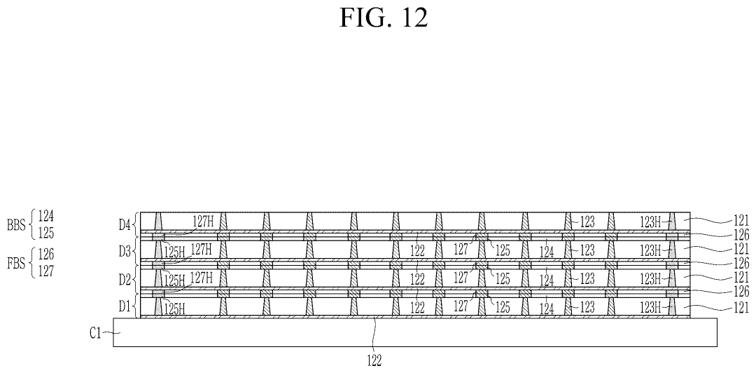

FIG. 12 is the cross-sectional view showing a step of sequentially stacking the second memory die D2, the third memory die D3, and the fourth memory die D4 on the first memory die D1.

Referring to FIG. 12, the hybrid bonding process may be performed to bond the second memory die D2 on the first memory die D1. The chemical mechanical polishing (CMP) process may be performed before the hybrid bonding. In some example embodiments, a surface roughness of each of the bonding surfaces on which the hybrid bonding is performed may be about 10 Å or less. Next, the bonding surface of the backside silicon insulating layer 124 on the first memory die D1 and the bonding surface of the frontside silicon insulating layer 126 on the second memory die D2 may be activated. In some example embodiments, the bonding surface of the backside silicon insulating layer 124 and the bonding surface of the frontside silicon insulating layer 126 may be surface treated by plasma activation. Next, the first memory die D1 and the second memory die D2 may be aligned for the hybrid bonding. Next, the activated bonding surface of the backside silicon insulating layer 124 on the first memory die D1 may contact the activated bonding surface of the frontside silicon insulating layer 126 on the second memory die D2 to perform pre-bonding.

Thereafter, the first memory die D1 and the second memory die D2 may be hybrid bonded. First, the backside silicon insulating layer 124 on the first memory die D1 and the frontside silicon insulating layer 126 on the second memory die D2 may be bonded by treatment. The treatment may strengthen bonding of the pre-bonded backside silicon insulating layer 124 on the first memory die D1 to the pre-bonded frontside silicon insulating layer 126 on the second memory die D2.

Next, each of the backside bonding pads 125 on the first memory die D1 and each of the frontside bonding pads 127 on the second memory die D2 may be bonded by annealing.

Thereafter, the same hybrid process may be performed to bond the third memory die D3 on the second memory die D2 and bond the fourth memory die D4 on the third memory die D3.

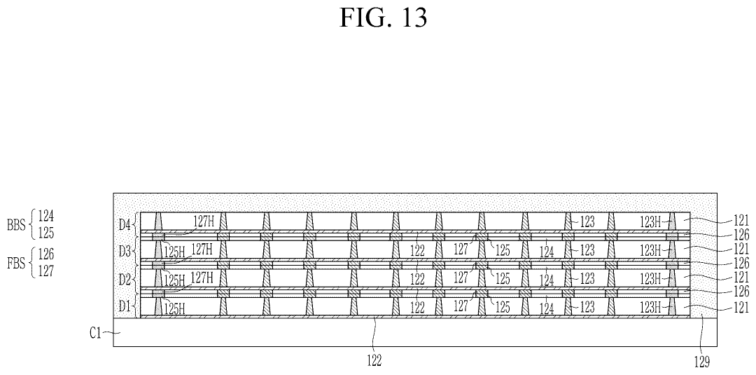

FIG. 13 is the cross-sectional view showing a step of molding the first memory die D1, the second memory die D2, the third memory die D3, and the fourth memory die D4 on the first carrier C1.

Referring to FIG. 13, the first memory die D1, the second memory die D2, the third memory die D3, and the fourth memory die D4 may be covered with the molding material 129 on the first carrier C1. In some example embodiments, the process of molding the first memory die D1, the second memory die D2, the third memory die D3, and the fourth memory die D4 with the molding material 129 may include a compression molding or transfer molding process. In some example embodiments, the molding material 129 may include an epoxy molding compound (EMC), but example embodiments are not limited thereto.

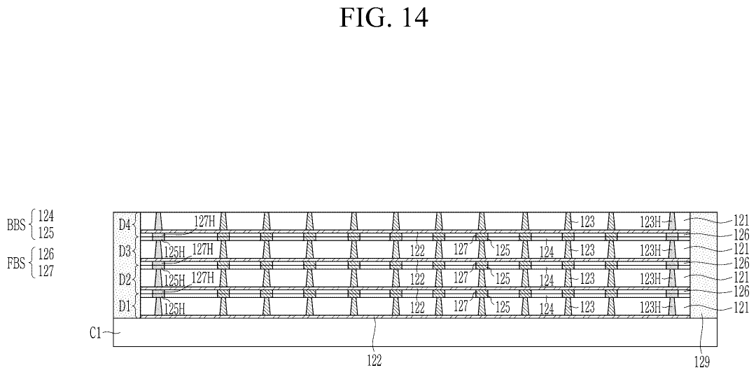

FIG. 14 is the cross-sectional view showing a step of performing a chemical mechanical polishing (CMP) process on the molding material 129.

Referring to FIG. 14, an upper surface of the molding material 129 may be planarized by performing the chemical mechanical polishing (CMP) process. After the chemical mechanical polishing (CMP) process is performed, an upper surface of the fourth memory die D4 may be exposed.

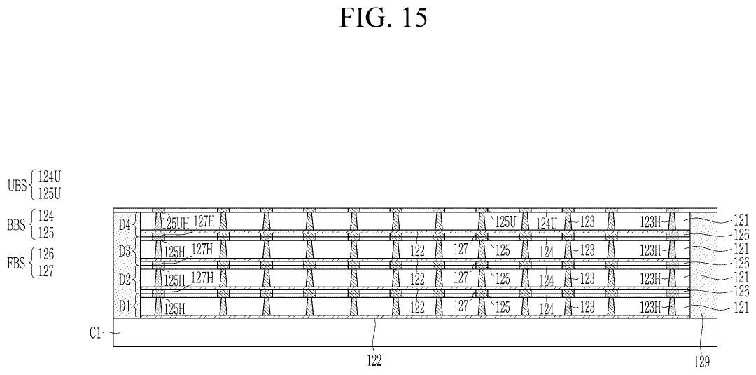

FIG. 15 is the cross-sectional view showing a step of forming the upper bonding structure UBS on the molding material 129 and the fourth memory die D4.

Referring to FIG. 15, the upper silicon insulating layer 124U may be formed on the molding material 129 and on the fourth memory die D4. Thereafter, a photolithography process and an etching process may be performed to form openings in which the upper bonding pads 125U are to be formed, and after a seed metal layer is applied, an electrolytic plating process may be performed so that the openings are filled to form the upper bonding pads 125U.

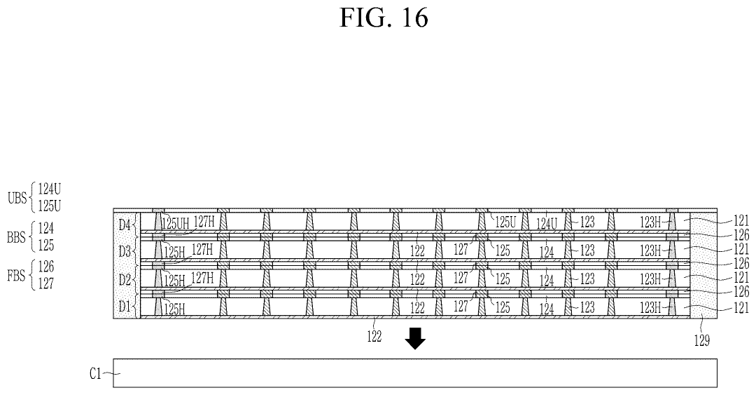

FIG. 16 is the cross-sectional view showing a step of removing the first carrier C1.

Referring to FIG. 16, the first carrier C1 may be removed from the first memory die D1 and the molding material 129.

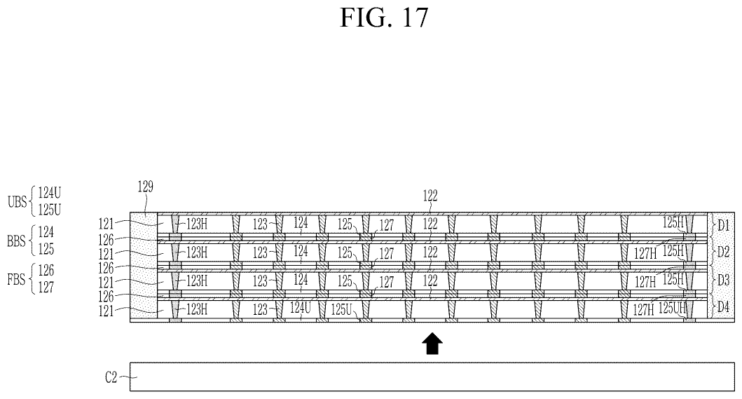

FIG. 17 is the cross-sectional view showing a step of attaching a second carrier C2.

Referring to FIG. 17, the second carrier C2 may be attached on the upper bonding structure UBS.

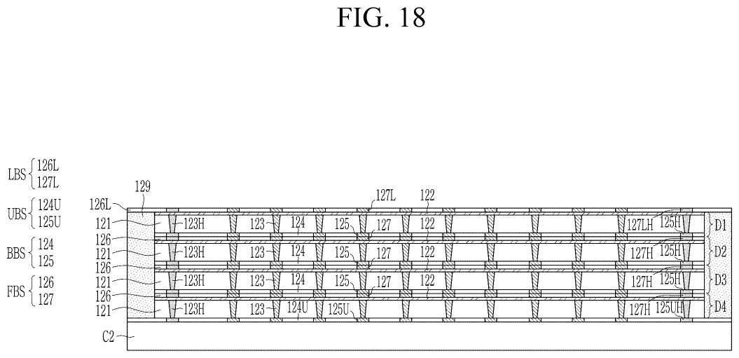

FIG. 18 is the cross-sectional view showing a step of forming the lower bonding structure LBS on the molding material 129 and the first memory die D1.

Referring to FIG. 18, the lower silicon insulating layer 126L may be deposited on the molding material 129 and the first memory die D1. Thereafter, a photolithography process and an etching process may be performed to form openings in which the lower bonding pads 127L are to be formed, and after a seed metal layer is applied, an electrolytic plating process may be performed so that the openings are filled to form the lower bonding pads 127L.

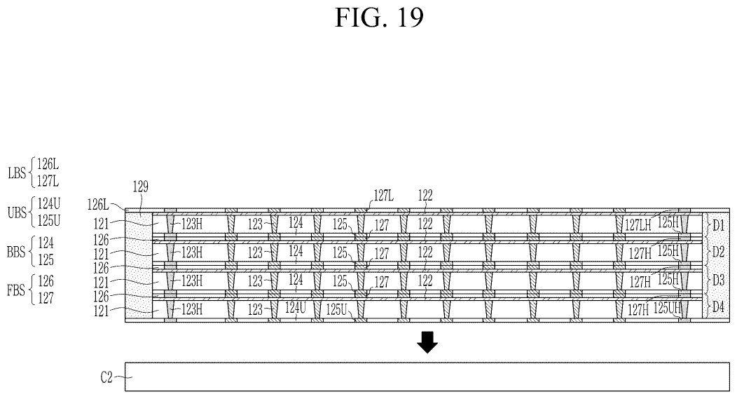

FIG. 19 is the cross-sectional view showing a step of removing the second carrier C2.

Referring to FIG. 19, the second carrier C2 may be removed from the upper bonding structure UBS.

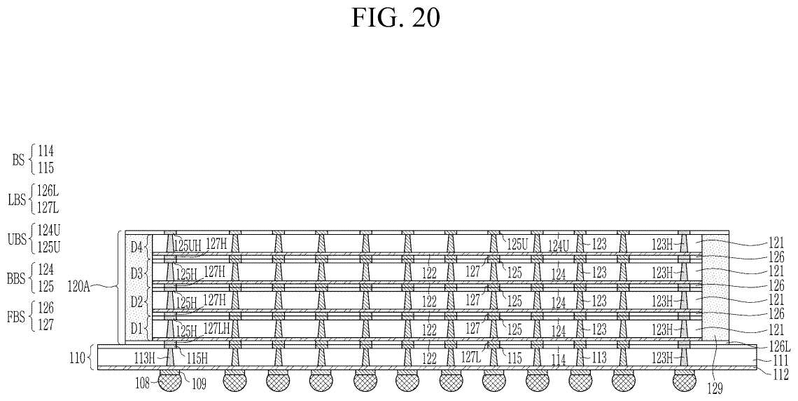

FIGS. 20 to 23 are cross-sectional views showing a method for manufacturing the high bandwidth memory 100C of FIG. 5.

FIG. 20 is the cross-sectional view showing a step of stacking the first memory stack structure 120A on the base die 110.

Referring to FIG. 20, a hybrid bonding process may be performed to bond the first memory stack structure 120A on the base die 110. The hybrid bonding process may be applied to the contents of the hybrid bonding process described with reference to FIG. 12.

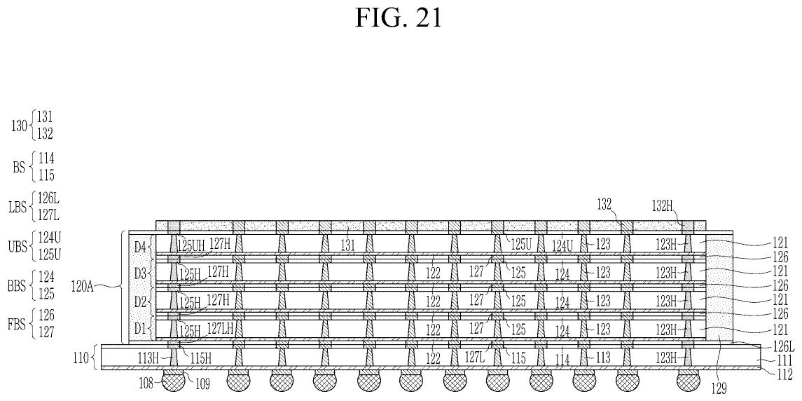

FIG. 21 is the cross-sectional view showing a step of stacking the glass core 130 on the first memory stack structure 120A.

Referring to FIG. 21, a hybrid bonding process may be performed to bond the glass core 130 on the first memory stack structure 120A.

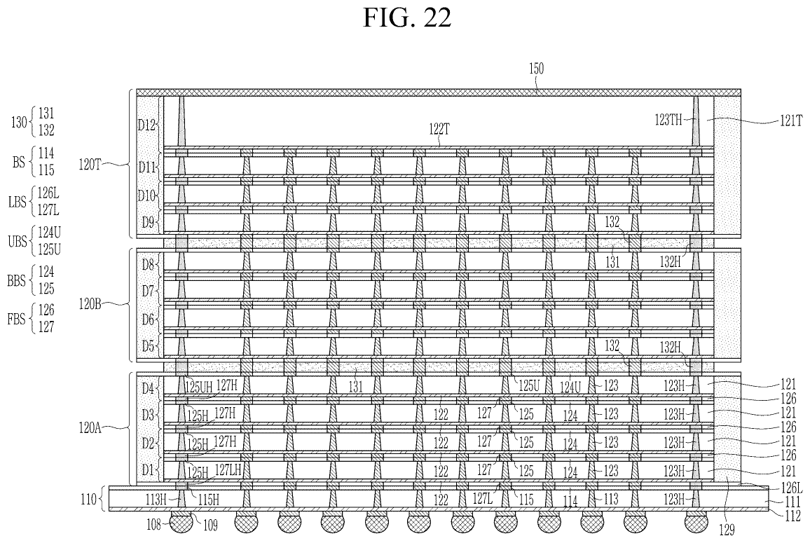

FIG. 22 is the cross-sectional view showing a step of stacking the second memory stack structure 120B, the glass core 130, and the third memory stack structure 120T on the glass core 130.

Referring to FIG. 22, the second memory stack structure 120B, the glass core 130, and the third memory stack structure 120T may be sequentially bonded on the glass core 130 by performing a hybrid bonding process.

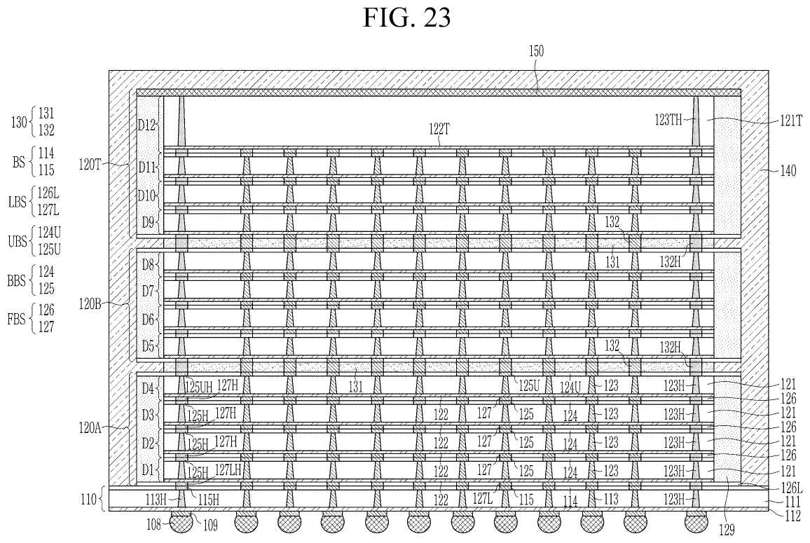

FIG. 23 is the cross-sectional view showing a step of molding the glass cores 130, the first memory stack structure 120A, the second memory stack structure 120B, and the third memory stack structure 120T on the base die 110.

Referring to FIG. 23, the glass cores 130, the first memory stack structure 120A, the second memory stack structure 120B, and the third memory stack structure 120T may be covered with the molding material 140 on the base die 110. In some example embodiments, the process of molding the glass cores 130, the first memory stack structure 120A, the second memory stack structure 120B, and the third memory stack structure 120T may include a compression molding or transfer molding process. In some example embodiments, the molding material 140 may include an epoxy molding compound (EMC). Thereafter, an upper surface of the molding material 140 may be planarized by performing a chemical mechanical polishing (CMP) process. After the chemical mechanical polishing (CMP) process is performed, an upper surface of the heat dissipation structure 150 may be exposed. Like the high bandwidth memory 100C shown in FIG. 5, the upper surface of the heat dissipation structure 150 may be exposed after the chemical mechanical planarization (CMP) process is performed.

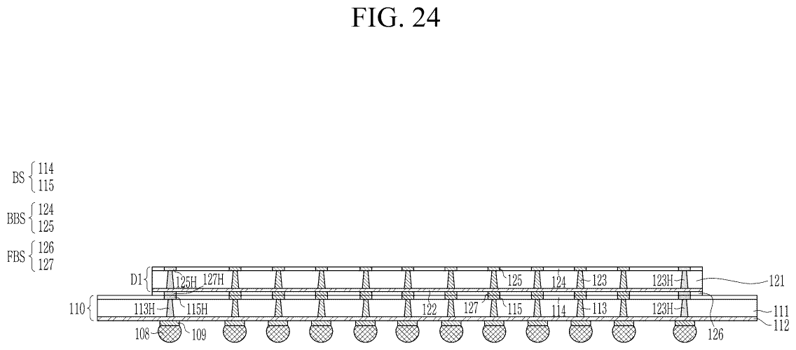

FIG. 24 to FIG. 31 are cross-sectional views showing a method for manufacturing the high bandwidth memory 100D of FIG. 6.

FIG. 24 is the cross-sectional view showing a step of stacking the first memory die D1 on the base die 110.

Referring to FIG. 24, the first memory die D1 may be bonded on the base die 110 by performing a hybrid bonding process. The hybrid bonding process may be applied to the contents of the hybrid bonding process described with reference to FIG. 12.

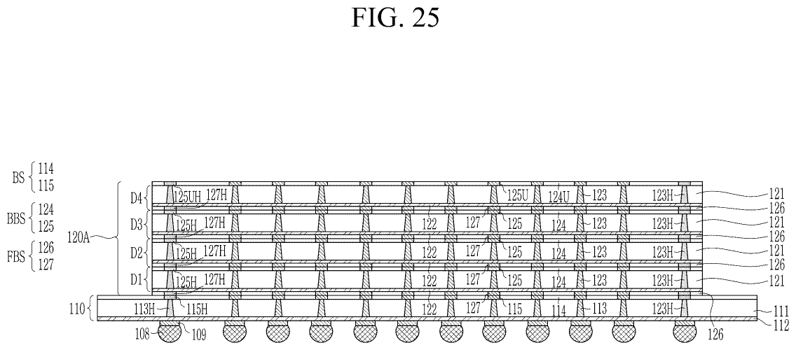

FIG. 25 is the cross-sectional view showing a step of sequentially stacking the second memory die D2, the third memory die D3, and the fourth memory die D4 on the first memory die D1.

Referring to FIG. 25, the second memory die D2, the third memory die D3, and the fourth memory die D4 may be sequentially bonded on the first memory die D1 by performing a hybrid bonding process.

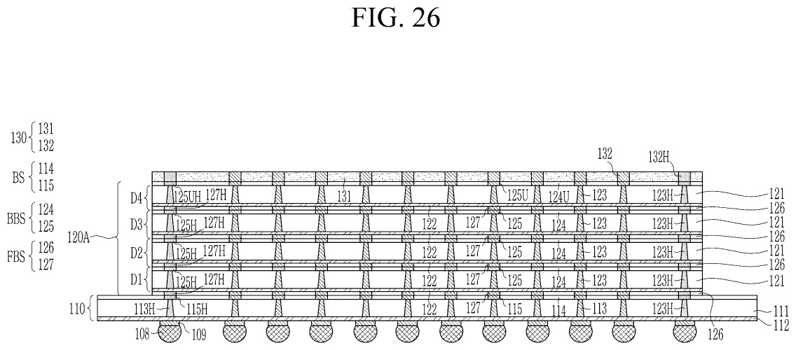

FIG. 26 is the cross-sectional view showing a step of stacking the glass core 130 on the fourth memory die D4.

Referring to FIG. 26, a hybrid bonding process may be performed to bond the glass core 130 on the fourth memory die D4.

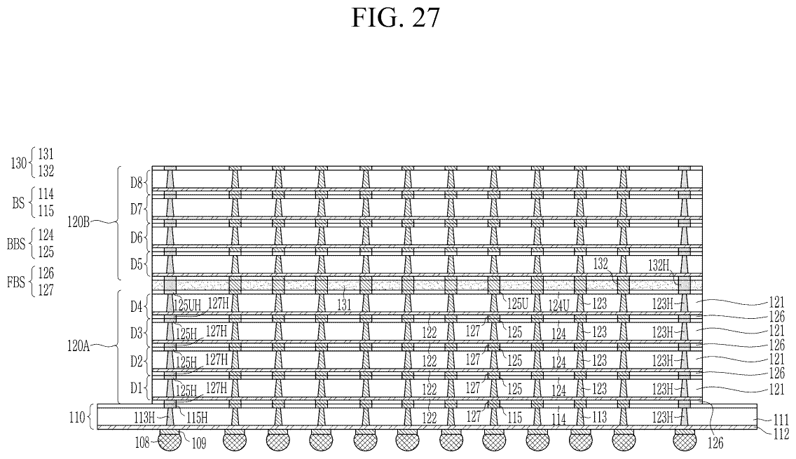

FIG. 27 is the cross-sectional view showing a step of sequentially stacking the fifth memory die D5, the sixth memory die D6, the seventh memory die D7, and the eighth memory die D8 on the glass core 130.

Referring to FIG. 27, the fifth memory die D5, the sixth memory die D6, the seventh memory die D7, and the eighth memory die D8 may be sequentially bonded on the glass core 130 by performing a hybrid bonding process.

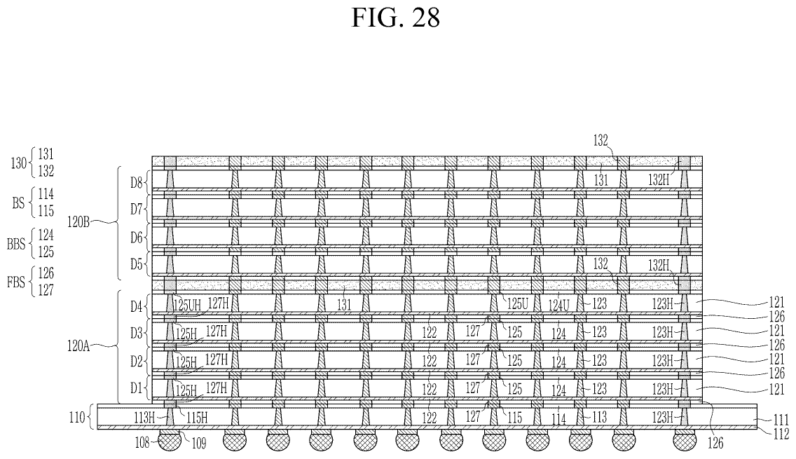

FIG. 28 is the cross-sectional view showing a step of stacking the glass core 130 on the eighth memory die D8.

Referring to FIG. 28, a hybrid bonding process may be performed to bond the glass core 130 on the eighth memory die D8.

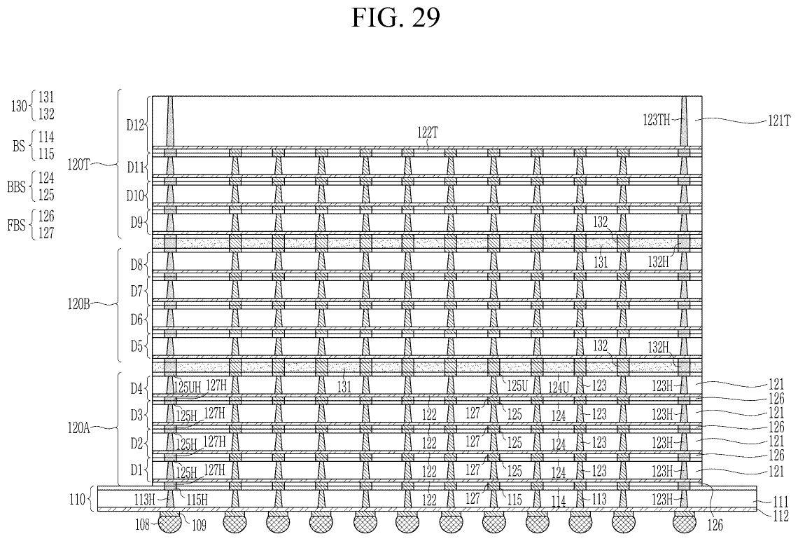

FIG. 29 is the cross-sectional view showing a step of sequentially stacking the ninth memory die D9, the tenth memory die D10, the eleventh memory die D11, and the twelfth memory die D12 on the glass core 130.

Referring to FIG. 29, a hybrid bonding process may be performed to sequentially bond the ninth memory die D9, the tenth memory die D10, the eleventh memory die D11, and the twelfth memory die D12 on the glass core 130.

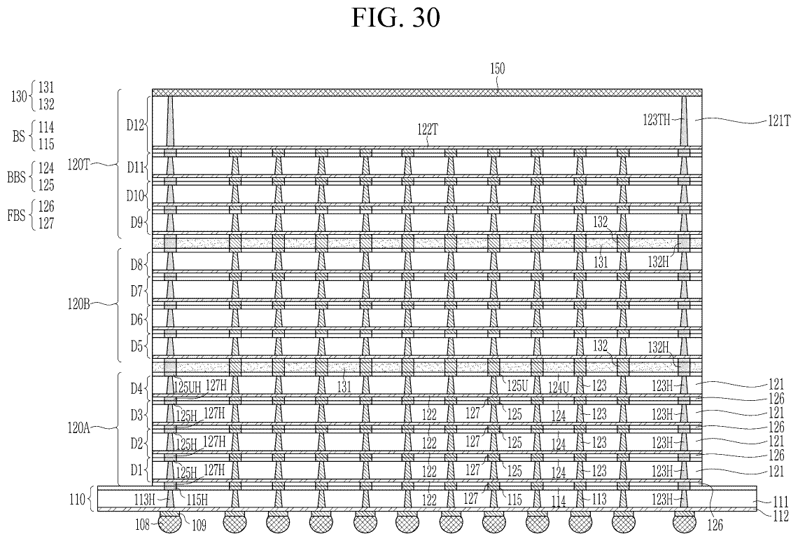

FIG. 30 is the cross-sectional view showing a step of attaching the heat dissipation structure 150 on the twelfth memory die D12.

Referring to FIG. 30, the heat dissipation structure 150 may be attached on the twelfth memory die D12.

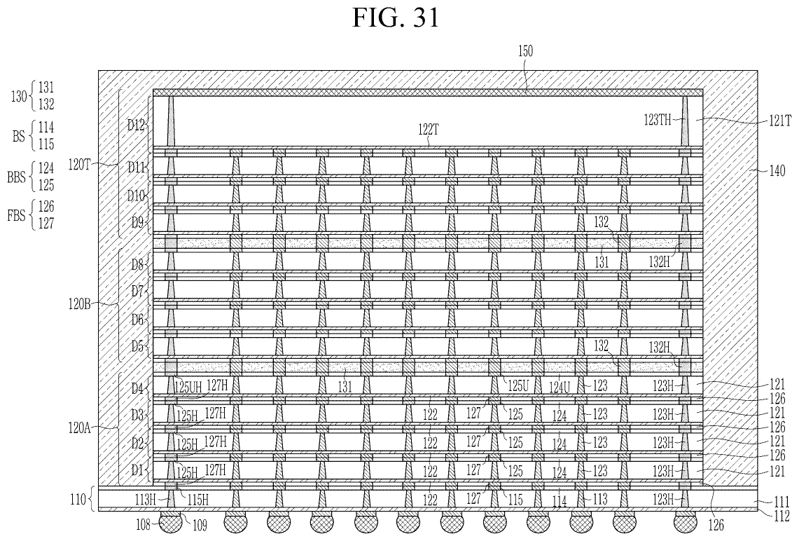

FIG. 31 is the cross-sectional view showing a step of molding the glass cores 130 and the first to twelfth memory dies D1 to D12 on the base die 110.

Referring to FIG. 31, the glass cores 130 and the first to twelfth memory dies D1 to D12 may be covered with the molding material 140 on the base die 110. In some example embodiments, the process of molding the glass cores 130 and the first to twelfth memory dies D1 to D12 may include a compression molding or transfer molding process. In some example embodiments, the molding material 140 may include an epoxy molding compound (EMC). Thereafter, an upper surface of the molding material 140 may be planarized by performing a chemical mechanical polishing (CMP) process. Like the high bandwidth memory 100D shown in FIG. 6, an upper surface of the heat dissipation structure 150 may be exposed after the chemical mechanical planarization (CMP) process is performed.

While this disclosure has been described in connection with some example embodiments, it should be understood that the disclosure is not limited to the disclosed example embodiments, but, on the contrary, is intended to cover various modifications and equivalent arrangements included within the spirit and scope of the appended claims.

What is claimed is:

1. A high bandwidth memory, comprising:
a first semiconductor stack including a plurality of first semiconductor dies stacked in a vertical direction;
a glass core on the first semiconductor stack; and
a second semiconductor stack on the glass core, the second semiconductor stack including a plurality of second semiconductor dies stacked in the vertical direction.

2. The high bandwidth memory of claim 1, wherein the glass core comprises:
a core base; and
a plurality of through-glass vias within the core base.

3. The high bandwidth memory of claim 2, wherein each first semiconductor die of the plurality of first semiconductor dies and each second semiconductor die of the plurality of second semiconductor dies includes
a die base;
a frontside silicon insulating layer on a frontside of the die base;
a plurality of frontside bonding pads penetrating the frontside silicon insulating layer;
a backside silicon insulating layer on a backside of the die base, the backside being opposite to the frontside of the die base; and
a plurality of backside bonding pads penetrating the backside silicon insulating layer.

4. The high bandwidth memory of claim 3, wherein
a first end of each through-glass via of the plurality of through-glass vias is bonded to a corresponding backside bonding pad among the plurality of backside bonding pads of the first semiconductor die at an uppermost portion of the first semiconductor stack, and
a second end opposite to the first end of each through-glass via of the plurality of through-glass vias is bonded to a corresponding frontside bonding pad among the plurality of frontside bonding pads of the second semiconductor die at a lowermost portion of the second semiconductor stack.

5. The high bandwidth memory of claim 3, wherein
a first surface of the core base is bonded to the backside silicon insulating layer of the first semiconductor die at an uppermost portion of the first semiconductor stack, and
a second surface opposite to the first surface of the core base is bonded to the frontside silicon insulating layer of the second semiconductor die at a lowermost portion of the second semiconductor stack.

6. The high bandwidth memory of claim 3, wherein
the glass core further comprises a first silicon insulating layer on a first surface of the core base and a second silicon insulating layer on a second surface of the core base, the second surface being opposite to the first surface of the core base, and
the plurality of through-glass vias penetrate the first silicon insulating layer and the second silicon insulating layer.

7. The high bandwidth memory of claim 6, wherein
the first silicon insulating layer is bonded to the backside silicon insulating layer of the first semiconductor die at an uppermost portion of the first semiconductor stack, and
the second silicon insulating layer is bonded to the frontside silicon insulating layer of the second semiconductor die at a lowermost portion of the second semiconductor stack.

8. A high bandwidth memory, comprising:
a base die;
a first memory stack structure on the base die, wherein the first memory stack structure includes a first lower bonding structure, a plurality of first memory dies stacked in a vertical direction on the first lower bonding structure, a first molding material covering the plurality of first memory dies on the first lower bonding structure, and a first upper bonding structure on the first molding material and the plurality of first memory dies;
a glass interposer on the first memory stack structure, wherein the glass interposer includes a core base and a plurality of through-glass vias within the core base; and
a second memory stack structure on the glass interposer, wherein the second memory stack structure includes a second lower bonding structure, a plurality of second memory dies stacked in the vertical direction on the second lower bonding structure, and a second molding material covering the plurality of second memory dies on the second lower bonding structure.

9. The high bandwidth memory of claim 8, wherein
the first upper bonding structure includes an upper silicon insulating layer and a plurality of upper bonding pads penetrating the upper silicon insulating layer, and
the second lower bonding structure includes a lower silicon insulating layer and a plurality of lower bonding pads penetrating the lower silicon insulating layer.

10. The high bandwidth memory of claim 9, wherein
a first end of each through-glass via of the plurality of through-glass vias is bonded to a corresponding upper bonding pad among the plurality of upper bonding pads, and
a second end opposite to the first end of each through-glass via of the plurality of through-glass vias is bonded to a corresponding lower bonding pad among the plurality of lower bonding pads.

11. The high bandwidth memory of claim 9, wherein
a first surface of the core base is bonded to the upper silicon insulating layer, and
a second surface opposite to the first surface of the core base is bonded to the lower silicon insulating layer.

12. The high bandwidth memory of claim 8, wherein a number of the plurality of first memory dies and a number of the plurality of second memory dies are different.

13. The high bandwidth memory of claim 8, wherein a number of the plurality of first memory dies and a number of the plurality of second memory dies are same.

14. The high bandwidth memory of claim 8, further comprising a third molding material covering the first memory stack structure, the glass interposer, and the second memory stack structure on the base die.

15. The high bandwidth memory of claim 14, wherein
each of side surfaces of the core base is recessed based on a corresponding one of side surfaces of the first molding material and a corresponding one of side surfaces of the second molding material, and
the third molding material extends to contact the side surfaces of the core base.

16. A high bandwidth memory, comprising:
a base die;
a plurality of memory stacks stacked in a vertical direction on the base die, wherein each memory stack of the plurality of memory stacks includes a plurality of memory dies stacked in the vertical direction;
one or more glass cores alternating with the plurality of memory stacks on the base die; and
a molding material covering the plurality of memory stacks and the one or more glass cores on the base die.

17. The high bandwidth memory of claim 16, further comprising a heat dissipation structure on the plurality of memory stacks.

18. The high bandwidth memory of claim 17, wherein the plurality of memory dies include a plurality of through-silicon vias electrically separated and thermally connected to the heat dissipation structure.

19. The high bandwidth memory of claim 16, wherein
the plurality of memory dies includes a first memory die and a second memory die, the first memory die and the second memory die being adjacent to a glass core of the one or more glass cores, and
the glass core includes a plurality of first through-glass vias electrically connecting the first memory die adjacent to the glass core to the second memory die adjacent to the glass core.

20. The high bandwidth memory of claim 17, wherein the one or more glass cores includes a plurality of second through-glass vias electrically separated and thermally connected to the heat dissipation structure.
